(19) United States
(12) Patent Application Publication
(10) Pub. No.: US 2017/0256561 A1
(43) Pub. Date: Sep. 7, 2017

(54) SEMICONDUCTOR DEVICE AND METHOD OF MANUFACTURING THE SAME

(71) Applicant: SK hynix Inc., Gyeonggi-do (KR)

(72) Inventor: Nam Jae LEE, Chungcheongbuk-do (KR)

(21) Appl. No.: 15/214,961

(22) Filed: Jul. 20, 2016

(30) Foreign Application Priority Data
Mar. 4, 2016 (KR) 10-2016-0026543

(51) Int. Cl. H01L 27/115; H01L 21/324; H01L 21/3065

(52) U.S. Cl. CPC H01L 27/11582; H01L 21/3065; H01L 21/324; H01L 27/11568

(57) ABSTRACT

Disclosed are a semiconductor device and a method of manufacturing the same. The semiconductor device includes: a lower layer and an etch catalyst layer which are sequentially stacked on a semiconductor substrate; a plurality of interlayer insulating layers and a plurality of conductive patterns, which are alternately stacked on the etch catalyst layer; and a channel plug passing through the plurality of interlayer insulating layers, the plurality of conductive patterns, and the etch catalyst layer, wherein inclination of a lower lateral wall of the channel plug is different from an inclination of an upper lateral wall of the channel plug.

### CROSS-REFERENCE TO RELATED APPLICATION

The present application claims a priority under 35 U.S.C. 119(a) to a Korean patent application number 10-2016-0026543 filed on Mar. 4, 2016, which is incorporated herein in its entirety by reference.

### BACKGROUND

1. Field

The present disclosure relates generally to an electronic device and, more particularly, to a semiconductor device having a vertical hole, and a method of manufacturing the same.

2. Description of the Related Art

A semiconductor device is generally classified into a volatile memory device and a nonvolatile memory device.

A nonvolatile memory device has a relatively low write and read rate, but maintains stored data even though a power supply to the device is turned off. Accordingly, the nonvolatile memory device is used for storing data, which needs to be maintained regardless of the power supply. Examples of nonvolatile memory devices include a Read Only Memory (ROM), a Mask ROM (MROM), a Programmable ROM (PROM), an Electrically Programmable ROM (EPROM), an Electrically Erasable and Programmable ROM (EEPROM), a flash memory, a Phase-change RAM (PRAM), a Magnetic RAM (MRAM), a Resistive RAM (RRAM), a Ferroelectric RAM (FRAM), and the like.

A flash memory may be a NOR or a NAND flash memory. A flash memory has the advantage of a Random Access Memory (RAM), in which data is freely programmed and erased, and also the advantage of a ROM, in which stored data can be maintained even though a power supply is blocked. The flash memory is widely used as a storage medium of portable electronic devices, such as digital cameras, Personal Digital Assistants (PDA), and MP3 players.

For improving the degree of integration of memory cells, a flash memory including a three-dimensional (3D) cell string, in which the memory cells are stacked on a substrate in multiple layers, has been suggested. The degree of integration of a 3D cell string increases when compared to two-dimensional cell arrays occupying the same cross-sectional flat area. A conventional process of forming a channel flag in a process of manufacturing the 3D cell string is performed by etching the stacked layers in the multiple layers. In this case, when the number of stacked layers is increased, a lower width of the channel plug is decreased, and thus there is a problem in that the memory cells may have different electrical characteristics according to their relative positioning in the channel.

### SUMMARY OF THE INVENTION

The present disclosure addresses the above-described problems associated with the prior art, and provides a semiconductor device with a vertical hole having an improved profile, and a method of manufacturing the same.

An exemplary embodiment of the present disclosure provides a semiconductor device, including: a lower layer and an etch catalyst layer which are sequentially stacked on a semiconductor substrate; a plurality of interlayer insulating layers and a plurality of conductive patterns, which are alternately stacked on the etch catalyst layer; and a channel plug passing through the plurality of interlayer insulating layers, the plurality of conductive patterns, and the etch catalyst layer, wherein inclination of a lower lateral wall of the channel plug is different from an inclination of an upper lateral wall of the channel plug.

Another exemplary embodiment of the present disclosure provides a semiconductor device, including: a conductive layer, an etch catalyst layer, and an interlayer insulating layer, which are sequentially stacked on a semiconductor substrate; and a contact plug passing through the plurality of interlayer insulating layers and the etch catalyst layer to be electrically connected to the conductive layer, wherein an inclination of an upper lateral wall of the contact plug is larger than an inclination of a lower lateral wall of the contact plug.

Yet another exemplary embodiment of the present disclosure provides a method of manufacturing a semiconductor device, including: sequentially stacking a lower layer and an etch catalyst layer on a semiconductor substrate; alternately stacking a plurality of interlayer insulating layers and a plurality of sacrificial layers on the etch catalyst layer; forming a channel hole, through which the etch catalyst layer is exposed, by etching the plurality of interlayer insulating layers and the plurality of sacrificial layers; and etching the exposed etch catalyst layer exposed by performing an etch process.

According to the exemplary embodiments of the present disclosure, a lower lateral wall of a vertical hole is additionally etched during a process of manufacturing a semiconductor device, so that it is possible to improve a profile of the vertical hole.

### BRIEF DESCRIPTION OF THE DRAWINGS

Various embodiments of the present invention will now be described more fully hereinafter with reference to the accompanying drawings in which:

FIGS. 1A to 1G are side, cross-sectional views of a semiconductor device illustrating a method of manufacturing the semiconductor device, according to an embodiment of the present invention.

FIGS. 2A to 2E are side, cross-sectional views of a semiconductor device illustrating a method of manufacturing the semiconductor device, according to another embodiment of the present invention.

FIG. 3 is a block diagram of a memory system including a semiconductor device, according to an embodiment of the present invention.

FIG. 4 is a block diagram illustrating an application example of the memory system of FIG. 3, according to an embodiment of the present invention.

FIG. 5 is a block diagram illustrating a computing system including the memory system of FIG. 4, according to an embodiment of the present invention.

### DETAILED DESCRIPTION OF THE INVENTION

Advantages and features of the present invention and methods of achieving the advantages and features will be described with reference to exemplary embodiments described in detail below together with the accompanying drawings. However, the present invention is not limited to the exemplary embodiments described herein, and may be implemented in various different forms. However, the exemplary embodiments described herein are provided so as to describe the present invention in detail so that those skilled in the art may easily make and use the present invention.

In describing the present invention, a publicly known configuration irrelevant to the principal point of the present invention may be omitted. It is noted that in giving reference numerals to elements of each drawing, like reference numerals may refer to like elements in different drawings.

It will be understood that, although the terms “first”, “second”, “third”, and so on may be used herein to describe various elements, these elements are not limited by these terms. These terms are used to distinguish one element from another element. Thus, a first element described below could also be termed as a second or third element without departing from the spirit and scope of the present invention.

The drawings are not necessarily to scale and, in some instances, proportions may have been exaggerated in order to clearly illustrate features of the embodiments. For example, in the drawings, the thicknesses and the intervals of elements may be exaggerated compared to an actual physical thickness for convenience of illustration.

It will be further understood that when an element is referred to as being “connected to”, or “coupled to” another element, it may be directly on, connected to, or coupled to the other element, or one or more intervening elements may be present. In addition, it will also be understood that when an element is referred to as being “between” two elements, it may be the only element between the two elements, or one or more intervening elements may also be present.

The terminology used herein is for the purpose of describing particular embodiments only and is not intended to be limiting of the present invention. As used herein, singular forms are intended to include the plural forms as well, unless the context clearly indicates otherwise. It will be further understood that the terms “comprises”, “comprising”, “includes”, and “including” when used in this specification, specify the presence of the stated elements and do not preclude the presence or addition of one or more other elements. As used herein, the term “and/or” includes any and all combinations of one or more of the associated listed items.

Unless otherwise defined, all terms including technical and scientific terms used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the present disclosure and the relevant art and will not be interpreted in an idealized or overly formal sense unless expressly so defined herein.

In the following description, numerous specific details are set forth in order to provide a thorough understanding of the present invention. The present invention may be practiced without some or all of these specific details. In other instances, well-known process structures and/or processes have not been described in detail in order not to unnecessarily obscure the present invention.

It is also noted, that in some instances, as would be apparent to those skilled in the relevant art, a feature or element described in connection with one embodiment may be used singly or in combination with other features or elements of another embodiment, unless otherwise specifically indicated.

Hereinafter, the various embodiments of the present invention will be described in detail with reference to the attached drawings.

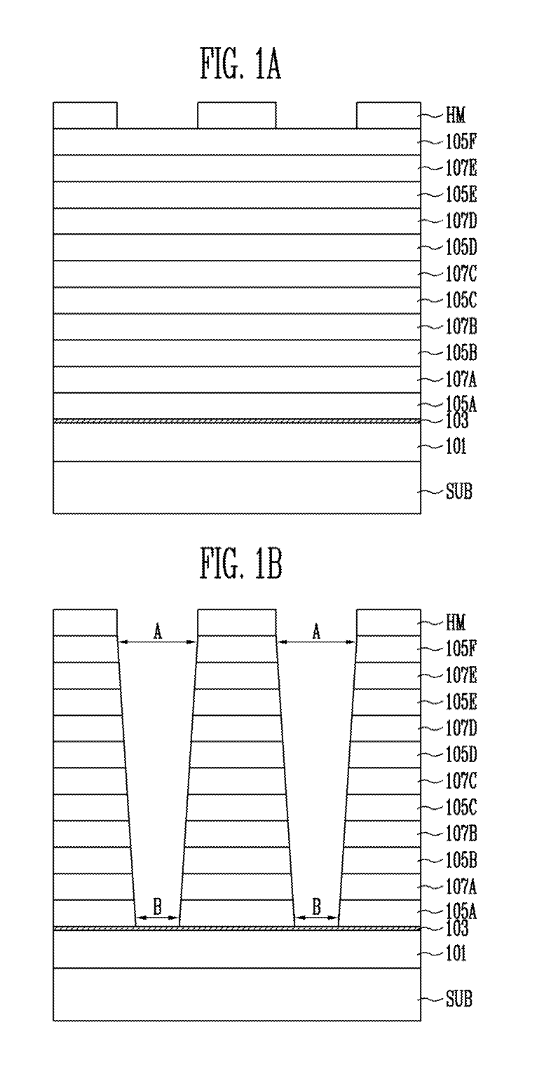

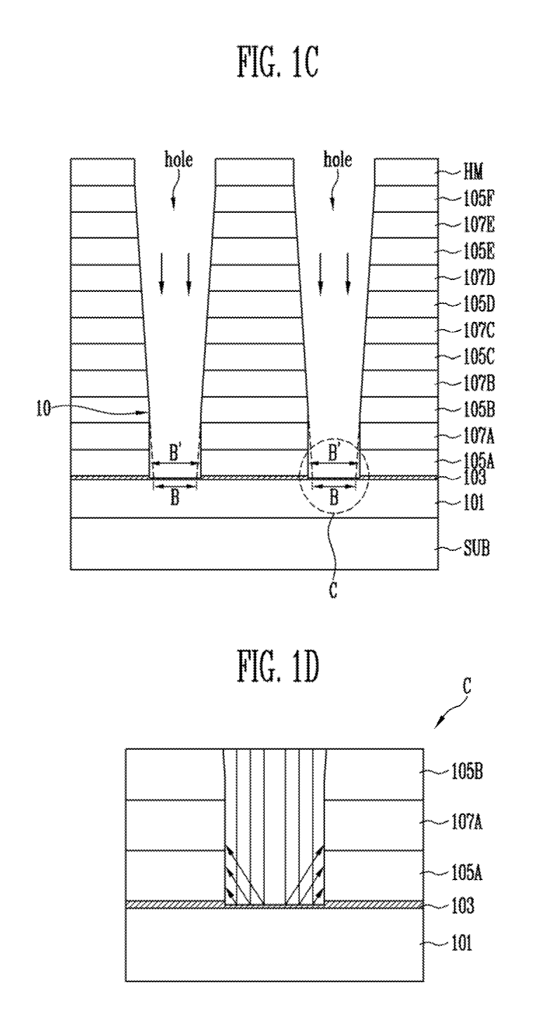

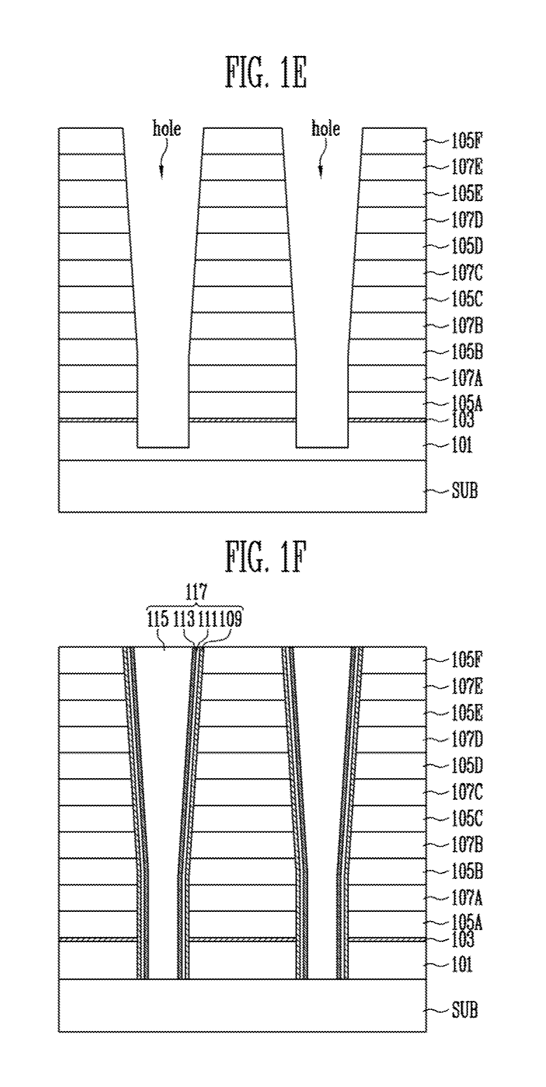

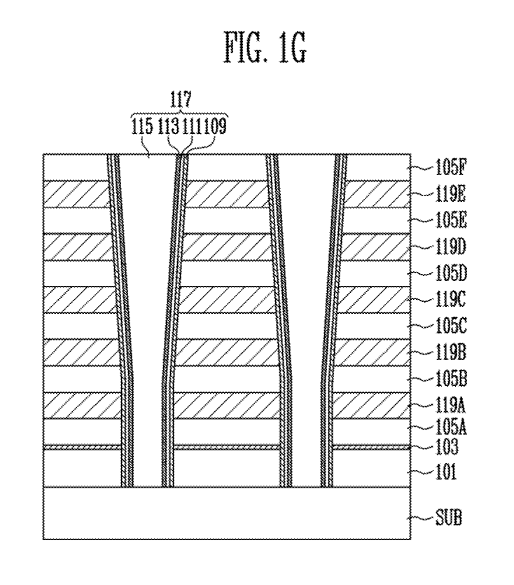

Referring now to FIGS. 1A to 1G a method of manufacturing a semiconductor device is provided, according to an embodiment of the present disclosure. More specifically, a method of manufacturing a semiconductor device including a vertical channel plug will be described as an example.

Referring to FIG. 1A, a lower layer 101 is formed on a substrate SUB. Next, an etch catalyst layer 103 is formed on the lower layer 101.

The lower layer 101 as illustrated in FIG. 1A is a single layer. For example, the lower layer 101 may be formed of a single polysilicon (poly-Si) layer. However, in a variation of the manufacturing method, the lower layer 101 may be formed in multiple layers, in which multiple polysilicon layers and multiple buffer oxide layers are alternately stacked. The buffer oxide layers may, for example, be layers of silicon oxide (SiO₂) deposited using chemical vapor deposition.

The etch catalyst layer 103 may, for example, be formed by depositing a Ti layer on the lower layer 101 and then performing a heat treatment process. The Ti layer deposited on the lower layer 101 may be converted into a titanium silicide TiSix layer, such as a TiSi₂, as a result of the heat treatment process. That is, the etch catalyst layer 103 may be formed of a TiSix layer.

Then, a plurality of interlayer insulating layers 105A to 105F and a plurality of sacrificial layers 107A to 107E are alternately stacked on the etch catalyst layer 103. The interlayer insulating layers 105A to 105F may be formed of silicon oxide layers. The sacrificial layers 107A to 107E may be formed of material layers, for example, silicon nitride layers, having etch selectivity for the interlayer insulating layers 105A to 105F.

Then, a hard mask pattern HM is formed on the interlayer insulating layer 105F stacked at the topmost portion. The hard mask pattern HM may be formed so that a portion of the hard mask pattern HM, in which a channel plug is to be formed, is opened.

Referring to FIG. 1B, a plurality of channel holes is formed by etching the interlayer insulating layers 105A to 105F and the sacrificial layers 107A to 107E by using the hard mask pattern HM as an etch barrier. In this way, the etch catalyst layer 103 is exposed at a lower portion of the channel hole.

Lateral walls of the channel hole are formed to be inclined, so that an upper width A of the channel hole is larger than a lower width B of the channel hole.

The etch process is performed so that the etch catalyst layer 103 is exposed. That is, the etch catalyst layer 103 serves as an etch stopping layer.

Referring to FIG. 1C, the exposed etch catalyst layer 103 is etched. In this case, the lower lateral walls of the channel hole may be additionally etched by by-products generated while the etch catalyst layer 103 is etched. Accordingly, the lower width of the channel hole may be increased from B to B′.

In this case, the channel hole may be divided in an upper portion and a lower portion based on an inflection point, at which an inclination of the lateral wall of the channel hole is changed. In FIG. 1C, one inflection point 10 is illustrated. However, in another embodiment of the manufacturing method, a plurality of inflection points may be formed using the etch process.

The lower portion C of the channel hole will be described below in more detail.

Referring to FIG. 1D, in the lower portion C of the channel hole, the by-products generated during the etch process of the etch catalyst layer 103 serve as etchants, so that the lower lateral wall of the channel hole is additionally etched. The etch process of the etch catalyst layer 103 may employ an O₂ plasma etch process using oxygen as source gas, by-products (TiO₂) may be generated by combining Ti, which is generated while the etch catalyst layer 103 is etched, and oxygen used as source gas during the etch process. This way the lower lateral wall of the channel hole may be additionally etched by the by-products. Accordingly, a critical dimension of the lower portion of the channel hole may be increased.

Referring to FIG. 1E, the channel hole is formed by etching the lower layer 101, which is exposed after the etch catalyst layer 103 is etched, by a predetermined thickness.

Thus, an inclination of the upper lateral wall of the channel hole may be formed to be smaller than an inclination of the lower lateral wall of the channel hole based on the semiconductor substrate SUB. The inclination as used herein refers to the acute angle formed between a lateral wall and the horizontal plane to which the substrate extends. Hence, a larger inclination means that the lateral wall is closer to being vertical.

In the illustrated embodiment of FIG. 1E, the upper lateral wall of the channel hole is formed to be inclined, whereas the lower lateral wall of the channel hole is formed to have a substantially vertical profile. Then, the hard mask pattern may be removed.

Referring to FIG. 1F, a channel plug 117 is formed inside the channel hole. The channel plug 117 may be formed of a charge storing layer 109, a tunnel insulating layer 111, and a channel layer 113, which are sequentially formed on the lateral walls of the channel holes. The charge storing layer 109 may be formed of a material layer, for example, a silicon nitride layer, in which charge trap is available. The tunnel insulating layer 111 may be formed of an insulating layer, for example, a silicon oxide layer, through which charges may be tunneled. The channel layer 113 is formed of a semiconductor material, such as silicon. The channel layer 113 may be formed in a tube form, of which a center region is empty, along a surface of the channel hole. In this case, an insulating layer 115 filled in the center region of the channel layer 113 in the tube form may be further formed.

Referring to FIG. 1G, the plurality of sacrificial layers is etched and removed, and conductive patterns 119A to 119E are formed by filling a conductive material in spaces, in which the plurality of sacrificial layers is removed. The conductive patterns 119A to 119E may be formed of a metal material, such as, for example, tungsten.

As described above, according to the illustrated embodiment of FIGS. 1A to 1G, the lower lateral walls of the channel hole is additionally etched by the by-products generated during the etch of the etch catalyst layer 103 during the process of forming the channel hole for forming the channel plug 117, so that a threshold value of the lower portion of the channel hole may be increased. Accordingly, a lower width of the channel plug 117 is increased, so that an electric characteristic of the memory cells may be improved.

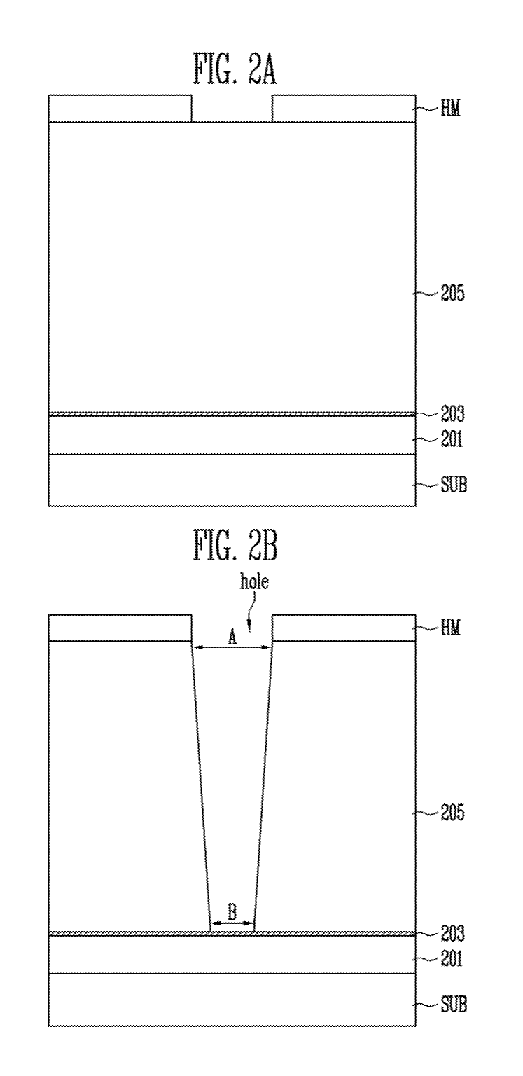

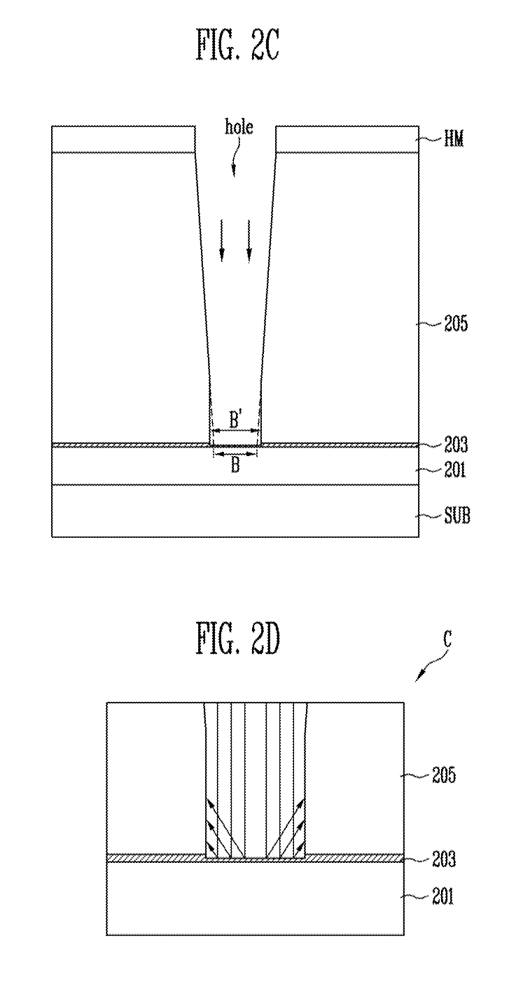

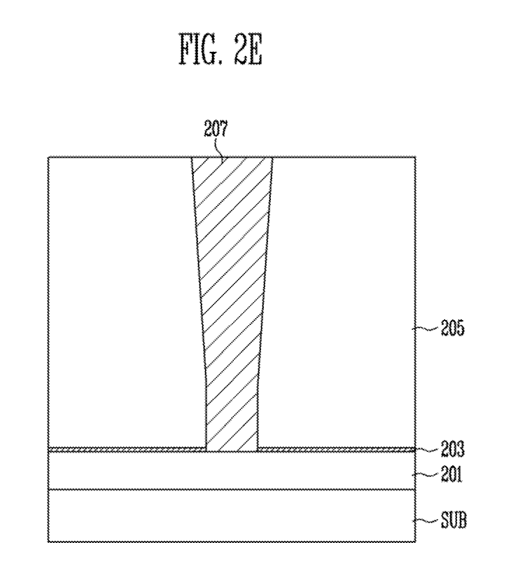

Referring now to FIGS. 2A to 2E a method of manufacturing a semiconductor device is provided, according to another embodiment of the present disclosure. More specifically, a method of manufacturing a semiconductor device including a contact plug will be described as an example.

Referring to FIG. 2A, a conductive layer 201 is formed on a substrate SUB. Next, an etch catalyst layer 203 is formed on the conductive layer 201.

In the exemplary embodiment of the present disclosure, the conductive layer 201 may be a wiring or junction region of the semiconductor device. In an embodiment, the conductive layer 201 may be formed of a polysilicon layer. In another embodiment, the conductive layer 201 may be formed by ion injection within the semiconductor substrate SUB.

The etch catalyst layer 203 may be formed by depositing a Ti layer on the conductive layer 201 and then performing a heat treatment process. The Ti layer deposited on the conductive layer 201 may be converted into a titanium silicide TiSix layer, such as, for example, of TiSi₂ as a result of the heat treatment process. That is, the etch catalyst layer 203 may be formed of a TiSix layer.

Then, an interlayer insulating layer 205 is formed on the etch catalyst layer 203. The interlayer insulating layer may be formed of an oxide layer, such as a silicon oxide (SiO₂). A hard mask pattern HM is formed on the interlayer insulating layer 205. The hard mask pattern HM may be formed so that a portion of the hard mask pattern HM, in which a contact plug is to be formed, is left clear of the hard mask material as shown in FIG. 2A.

Referring to FIG. 2B, a contact hole is formed by etching the interlayer insulating layer 205 by using the hard mask pattern HM as an etch barrier. The lateral walls of the contact hole are formed to be inclined, and an upper width A of the contact hole is larger than a lower width B of the contact hole.

The etch process is continued so that the etch catalyst layer 203 is exposed.

Referring to FIG. 2C, the exposed etch catalyst layer 203 is also etched by the etch process. While the etch catalyst layer 203 is etched the lower lateral walls of the contact hole are also additionally etched by the generated by-products. Accordingly, the lower width of the contact hole may be increased from B to B′.

The lower portion C of the contact hole will be described below in more detail.

Referring to FIG. 2D, in the lower portion C of the contact hole, the lower lateral wall of the contact hole is additionally etched by by-products generated during the etch of the etch catalyst layer 203. In this case, the etch process of the etch catalyst layer 203 may use an O₂ plasma etch process using oxygen as source gas, by-products (TiO₂) may be generated by combining Ti, which is generated while the etch catalyst layer 203 is etched, and oxygen used as source gas during the etch process, and the lower lateral wall of the contact hole may be additionally etched by the by-products. Accordingly, the width of the lower portion of the channel hole and a threshold value of the lower portion of the contact hole may be increased.

Accordingly, an inclination of the upper lateral wall of the contact hole may be formed to be smaller than an inclination of the lower lateral wall of the contact hole based on the semiconductor substrate SUB. In an embodiment, an upper lateral wall of the contact hole may be formed to be inclined, and the lower lateral wall of the contact hole may be formed to have a vertical profile.

Referring to FIG. 2E, a contact plug 207, which is in contact with the conductive layer 201, is formed by filling the contact hole with a conductive material after etching the etch catalyst layer 203.

As described above, according to the exemplary embodiment of the present disclosure, the lower lateral walls of the contact hole is additionally etched by the by-products generated during the etch of the etch catalyst layer 203 during the process of forming the contact hole for forming the contact plug 207, so that a threshold value of the lower portion of the contact hole may be increased. Accordingly, it is possible to improve an electrical characteristic of the semiconductor device by increasing a lower width of the contact plug 117.

Referring now to FIG. 3 a memory system including a semiconductor device is provided, according to an embodiment of the present disclosure.

According to the embodiment of FIG. 3, the memory system 1000 includes a semiconductor device 100 and a controller 1100.

The semiconductor device 100 may be a semiconductor device, such as a 3D flash memory device manufactured according to the manufacturing processes, described with reference to FIGS. 1A to 1F, and/or FIGS. 2A to 2E. The semiconductor device 100 is not limited to a flash memory device. Any semiconductor device may be employed having the characteristics of the semiconductor device manufactured according to the aforementioned manufacturing processes. For example, a semiconductor device may include a plurality of channels, wherein each channel has an upper portion and a lower portion, wherein the lateral walls of the upper channel portion have a smaller inclination than the lateral walls of the lower channel portion. In an embodiment, a semiconductor device may include a plurality of channels, wherein each channel has an upper portion and a lower portion, wherein the lateral walls of the upper channel portion have a smaller inclination than the lateral walls of the lower channel portion which are substantially vertical.

The controller 1100 is connected to a host Host and the semiconductor device 100. The controller 1100 is configured to access the semiconductor device 100 in response to a request from the host Host. For example, the controller 1100 is configured to control the read, write, erase, and background operations of the semiconductor device 100. The controller 1100 is configured to provide an interface between the semiconductor device 100 and the host Host. The controller 1100 is configured to drive firmware for controlling the semiconductor device 100.

The controller 1100 includes a Random Access Memory (RAM) 1110, a processing unit 1120, a host interface 1130, a memory interface 1140, and an error correction block 1150 linked via an internal bus. The RAM 1110 is used as at least one among a working memory of the processing unit 1120, a cache memory between the semiconductor device 100 and the host Host, and a buffer memory between the semiconductor device 100 and the host Host. The processing unit 1120 controls a general operation of the controller 1100. Further, the controller 1100 may temporarily store program data provided from the host Host during the write operation.

The host interface 1130 includes a protocol for performing a data exchange between the host Host and the controller 1100. As an exemplified embodiment, the controller 1100 is configured to communicate with the host Host through at least one of various interface protocols, such as a Universal Serial Bus (USB) protocol, a Multimedia Card (MMC) protocol, a Peripheral Component Interconnection (PCI) protocol, a PCI-express (PCI-E) protocol, an Advanced Technology Attachment (ATA) protocol, a Serial-ATA protocol, a Parallel-ATA protocol, a small computer small interface (SCSI) protocol, an enhanced small disk interface (ESDI) protocol, and an Integrated Drive Electronics (IDE) protocol, and a private protocol.

The memory interface 1140 interfaces with the semiconductor device 100. For example, the memory interface includes a NAND interface or a NOR interface.

The error correction block 1150 is configured to detect and correct an error of the data received from the semiconductor device 100 by using an Error Correction Code (ECC). The processing unit 1120 may control the semiconductor device 100 so as to adjust a read voltage according to a result of the error detection of the error correction block 1150 and perform a re-read operation. As an exemplified embodiment, the error correction block may be provided as a constituent element of the controller 1100.

The controller 1100 and the semiconductor device 100 may be integrated into one semiconductor device. As an exemplified embodiment, the controller 1100 and the semiconductor device 100 may be integrated into one semiconductor device to configure a memory card. For example, the controller 1100 and the semiconductor device 100 may be integrated into one semiconductor device to configure a memory card, such as a PC card (Personal Computer Memory Card International Association (PCMCIA)), a Compact Flash (CF) card, Smart Media Cards (SM, SMC), a memory stick, multimedia cards (MMC, RS-MMC, and MMCmicro), SD cards (SD, miniSD, microSD, and SDHC), and a Universal Flash Storage (UFS).

The controller 1100 and the semiconductor device 100 may be integrated into one semiconductor device to configure a semiconductor drive (Solid State Drive (SSD)). The semiconductor drive (SSD) includes a storage device configured to store data in a semiconductor memory. In a case where the memory system 1000 is used as the SSD, a speed of the operation of the host Host connected to the memory system 2000 is remarkably improved.

For another example, the memory system 1000 is provided as one of various constituent elements of an electronic device, such as a computer, an ultra mobile PC (UMPC, a workstation, a net-book computer, personal digital assistants (PDA), a portable computer, a web tablet PC, a wireless phone, a mobile phone, a smart phone, an e-book reader, a portable multimedia player (PMP), a portable game device, a navigation device, a black box, a digital camera, a 3-dimensional television, a digital audio recorder, a digital audio player, a digital picture recorder, a digital picture player, a digital video recorder, a digital video player, a device capable transceiving information in a wireless environment, one of various electronic devices configuring a home network, one of various electronic devices configuring a computer network, one of various electronic devices configuring a telematics network, an RFID device, or one of various constituent elements devices configuring a computing system.

For an exemplified embodiment, the semiconductor device 100 or the memory system 1000 may be embedded in various types of packages. For example, the semiconductor device 100 or the memory system 2000 may be packaged and embedded by a method, such as Package on Package (PoP), Ball Grid Arrays (BGAs), Chip Scale Packages (CSPs), Plastic Leaded Chip Carrier (PLCC), Plastic Dual In Line Package (PDIP), Die in Waffle Pack, Die in Wafer Form, Chip On Board (COB), Ceramic Dual In Line Package (CERDIP), Plastic Metric Quad Flat Pack (MQFP), Thin Quad Flat pack (TQFP), Small Outline (SOIC), Shrink Small Outline Package (SSOP), Thin Small Outline (TSOP), Thin Quad Flat pack (TQFP), System In Package (SIP), Multi Chip Package (MCP), Wafer-level Fabricated Package (WFP), and Wafer-Level Processed Stack Package (WSP).

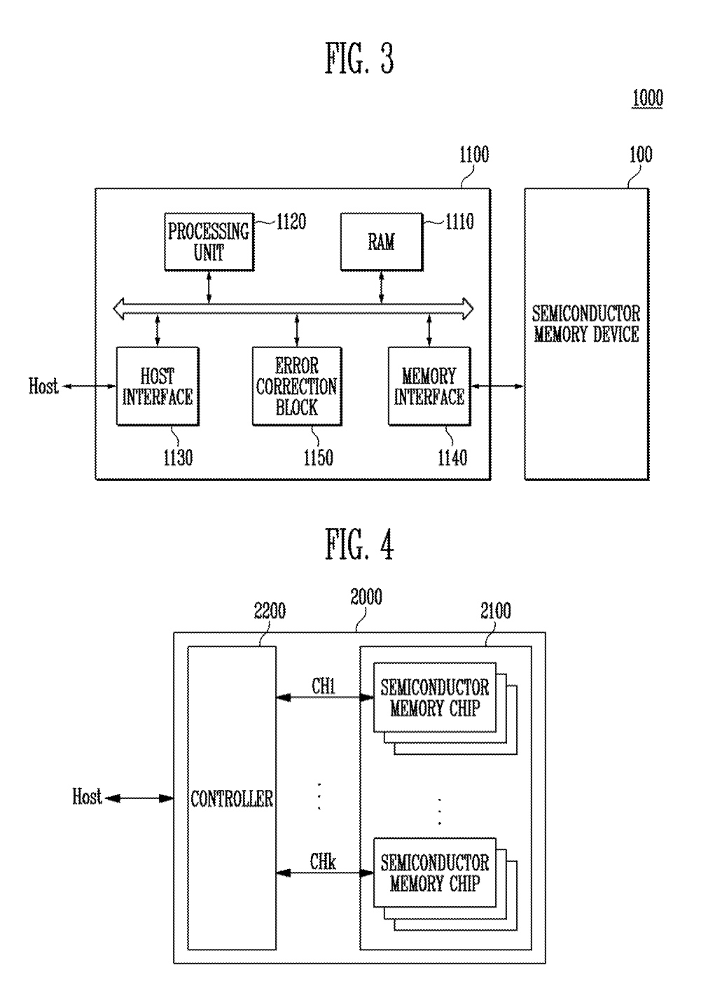

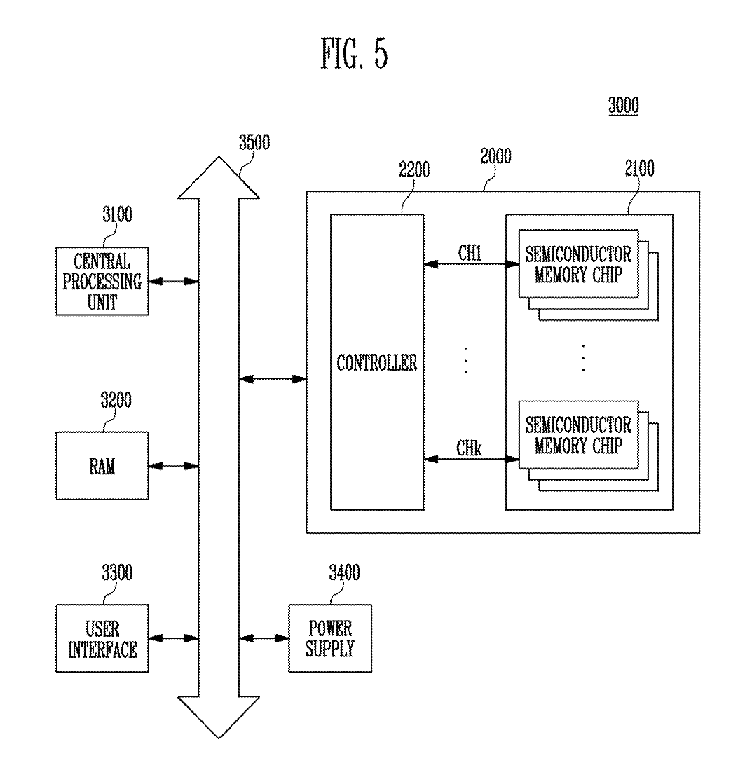

FIG. 4 is a block diagram illustrating an application example of the memory system of FIG. 3.

Referring to FIG. 4, the memory system 2000 includes a semiconductor device 2100 and a controller 2200. The semiconductor device 2100 includes a plurality of semiconductor memory chips. The plurality of semiconductor memory chips is divided into a plurality of groups.

In FIG. 4, it is illustrated that the plurality of groups communicates with the controller 2200 through first to k^{th} channels CH1 to CHk, respectively. Each semiconductor memory chip is configured and operated in a similar matter to the semiconductor device manufactured according to the exemplary embodiment or another exemplary embodiment of the present disclosure.

Each group is configured to communicate with the controller 2200 through one common channel. The controller 2200 is configured in a similar manner to that of the controller 1100 described with reference to FIG. 3, and is configured to control the plurality of memory chips of the semiconductor device 2100 through the plurality of channels CH1 to CHk.

FIG. 5 is a block diagram illustrating a computing system including the memory system described with reference to FIG. 4.

Referring to FIG. 5, a computing system 3000 includes a central processing unit 3100, a Random Access Memory (RAM) 3200, a user interface 3300, a power supply 3400, a system bus 3500, and the memory system 2000.

The memory system 2000 is electrically connected to the central processing unit 3100, the RAM 3200, the user interface 3300, and the power supply 3400 through the system bus 3500. Data provided through the user interface 3300 or processed by the central processing unit 3100 is stored in the memory system 2000.

In FIG. 5, it is illustrated that the semiconductor device 2100 is connected to the system bus 3500 through the controller 2200. However, the semiconductor device 2100 may be configured to be directly connected to the system bus 3500. In this case, a function of the controller 2200 may be performed by the central processing unit 3100 and the RAM 3200.

In FIG. 5, it is illustrated that the memory system 2000 described with reference to FIG. 4 is provided. However, the memory system 3000 may be substituted with the memory system 1000 described with reference to FIG. 3. As an exemplary embodiment, the computing system 3000 may be configured to include all of the memory systems 1000 and 2000 described with reference to FIGS. 3 and 4.

The technical spirit of the present disclosure have been described according to the exemplary embodiment in detail, but the exemplary embodiment has described herein for purposes of illustration and does not limit the present disclosure. Further, those skilled in the art will appreciate that various exemplary embodiments may be made within the technical spirit of the present disclosure.

What is claimed is:

1. A semiconductor device, comprising:
a lower layer and an etch catalyst layer, which are sequentially stacked on a semiconductor substrate;
a plurality of interlayer insulating layers and a plurality of conductive patterns, which are alternately stacked on the etch catalyst layer; and
a channel plug passing through the plurality of interlayer insulating layers, the plurality of conductive patterns, and the etch catalyst layer,
wherein an inclination of a lower lateral wall of the channel plug is different from an inclination of an upper lateral wall of the channel plug.

2. The semiconductor device of claim 1, wherein the inclination of the upper lateral wall of the channel plug is smaller than the inclination of the lower lateral wall of the channel plug.

3. The semiconductor device of claim 1, wherein the lateral wall of the channel plug is divided into the upper lateral wall and the lower lateral wall based on an inflection point, at which an inclination of the lateral wall is changed.

4. The semiconductor device of claim 1, wherein the lower layer is a silicon layer of a single layer, or multiple stacked layers, in which a plurality of poly silicon layers and a plurality of buffer oxide layers are alternately stacked.

5. The semiconductor device of claim 1, wherein the etch catalyst layer includes Ti.

6. The semiconductor device of claim 1, wherein the lower lateral wall of the channel plug has a vertical profile.

7. The semiconductor device of claim 1, wherein the channel plug includes:
a channel layer;
a tunnel insulating layer surrounding the channel layer; and
a charge storing layer surrounding the tunnel insulating layer.

8. A semiconductor device, comprising:
a conductive layer, an etch catalyst layer, and an interlayer insulating layer, which are sequentially stacked on a semiconductor substrate; and
a contact plug passing through the plurality of interlayer insulating layers and the etch catalyst layer to be electrically connected to the conductive layer,
wherein an inclination of an upper lateral wall of the contact plug is smaller than an inclination of a lower lateral wall of the contact plug.

9. The semiconductor device of claim 8, wherein the conductive layer is a wiring or junction region.

10. The semiconductor device of claim 8, wherein the etch catalyst layer includes Ti.

11. The semiconductor device of claim 8, wherein the lower lateral wall of the contact plug has a vertical profile.

12. A method of manufacturing a semiconductor device, comprising:
sequentially stacking a lower layer and an etch catalyst layer on a semiconductor substrate;
alternately stacking a plurality of interlayer insulating layers and a plurality of sacrificial layers on the etch catalyst layer;
forming a channel hole, through which the etch catalyst layer is exposed, by etching the plurality of interlayer insulating layers and the plurality of sacrificial layers; and
etching the exposed etch catalyst layer exposed by performing an etch process.

13. The method of claim 12, wherein a lower lateral wall of the channel hole is additionally etched by by-products of the etch catalyst layer are generated by the etch process.

14. The method of claim 12, wherein the lower layer is a silicon layer of a single layer, or is formed in multiple stacked layers, in which a plurality of poly silicon layers and a plurality of buffer oxide layers are alternately stacked.

15. The method of claim 12, wherein the etch catalyst layer is formed of a layer including Ti.

16. The method of claim 12, wherein the etch catalyst layer is formed by depositing a Ti layer on the lower layer and then converting the Ti layer into a TiSix layer by performing a heat treatment process.

17. The method of claim 12, wherein the etch process includes a plasma etch process including O₂.

18. The method of claim 12, wherein Ti, which is generated by the etch of the etch catalyst layer, and O₂, which is source gas of the etch process, are combined during the etch process, so that TiO₂ is generated as the by-products.

19. The method of claim 12, wherein during the etching of the exposed etch catalyst layer is performed so that an inclination of an upper lateral wall of the channel hole is formed to be smaller than an inclination of a lower lateral wall of the channel hole.

20. The method of claim 12, further comprising forming a channel plug by sequentially stacking a charge storing layer, a tunnel insulating layer, and a channel layer on a lateral wall of the channel hole after etching the etch catalyst layer.
